(19) United States
(12) Patent Application Publication
(10) Pub. No.: US 2013/0014984 A1
(43) Pub. Date: Jan. 17, 2013

(54) ELECTROMAGNETIC WAVE ABSORBER, METHOD OF PRODUCING THE SAME, FLEXIBLE PRINTED WIRING BOARD AND ELECTRONIC DEVICE

(71) Applicants: Hironori Iida, Kanagawa (JP); Shun Yamanoi, Kanagawa (JP); Machiko Minatoya, Tokyo (JP); Seiichiro Tabata, Kanagawa (JP); Shinichiro Yamada, Kanagawa (JP); Masayoshi Kanno, Kanagawa (JP); Masakazu Mitsugi, Kanagawa (JP); Yoshihiro Kato, Kanagawa (JP)

(72) Inventors: Hironori Iida, Kanagawa (JP); Shun Yamanoi, Kanagawa (JP); Machiko Minatoya, Tokyo (JP); Seiichiro Tabata, Kanagawa (JP); Shinichiro Yamada, Kanagawa (JP); Masayoshi Kanno, Kanagawa (JP); Masakazu Mitsugi, Kanagawa (JP); Yoshihiro Kato, Kanagawa (JP)

(73) Assignee: SONY CORPORATION, Tokyo (JP)

(21) Appl. No.: 13/536,560

(22) Filed: Jun. 28, 2012

(30) Foreign Application Priority Data
Jul. 14, 2011 (JP) 2011-155629

(51) Int. Cl. H05K 9/00; C09K 3/00

(52) U.S. Cl. 174/388; 252/600

(57) ABSTRACT

Provided is an electromagnetic wave absorber, including a base material and a porous carbon material containing, as a raw material, a plant-based material having a silicon content of 5% by mass or more, in which the porous carbon material has a specific surface area value as measured by the nitrogen BET method of 400 m²/g or more, a silicon content of 1% by mass or less, a pore volume as measured by the BJH method of 0.2 cm³/g or more, and a pore volume as measured by the MP method of 0.2 cm³/g or more, or a total pore volume of pores each having a diameter in the range from 1×10⁻⁹ m to 5×10⁻⁷ m as measured by the Non Localized Density Functional Theory of 1.0 cm³/g or more.

### CROSS REFERENCES TO RELATED APPLICATIONS

The present application claims priority to Japanese Priority Patent Application JP 2011-155629 filed in the Japan Patent Office on Jul. 14, 2011, the entire content of which is hereby incorporated by reference.

### BACKGROUND

The present disclosure relates to an electromagnetic wave absorber, a method of producing the same, a flexible printed wiring board and an electronic device.

In recent years, along with miniaturization and high operating speed of electronic devices, electromagnetic noises produced by various types of electromagnetic waves emitted from the electronic devices are unfavorably increased. In addition, it has been reported that the electromagnetic noises may not only cause malfunction of the electronic device, but also cause leukemia, a cancer and the like. As means for solving these problems of the electromagnetic noises, an electromagnetic wave absorber can be, for example, applied to the electronic device. A mechanism of absorbing the electromagnetic waves by the electromagnetic wave absorber utilizes conductivity, dielectricity or magnetism. A variety of electromagnetic wave absorbers have been developed. Among them, attention is drawn to an electromagnetic wave absorber including a carbon material, because such absorber has a weight lighter than other materials and is rich in flexibility. For example, Japanese Unexamined Patent Application Publication No. 2010-161337 discloses the technology that a conductive composition is produced by burning a plant including a grain residue such as soybean hull, rapeseed oil cake, rice bran, or chaff at 900° C. for about 3 hours to provide a burned plant material, and mixing 100 parts by mass or more of the burned plant material with a base material such as ethylene-propylene-diene rubber.

### SUMMARY

However, the electromagnetic wave absorber including the carbon material which has been developed in the past, e.g., the electromagnetic wave absorber disclosed in the above-mentioned Japanese Unexamined Patent Application Publication No. 2010-161337 has a disadvantage of not showing sufficient electromagnetic wave absorbing properties.

Thus, it is desirable to provide an electromagnetic wave absorber having high electromagnetic wave absorbing properties, a method of producing the same, a flexible printed wiring board including the electromagnetic wave absorber and an electronic device including the electromagnetic wave absorber.

According to a first embodiment of the present disclosure, there is provided an electromagnetic wave absorber, including a base material and a porous carbon material containing, as a raw material, a plant-based material having a silicon (Si) content of 5% by mass or more, in which the porous carbon material has a specific surface area value as measured by the nitrogen BET method of 400 m²/g or more, a silicon (Si) content of 1% by mass or less, a pore volume as measured by the BJH method of 0.2 cm³/g or more, and a pore volume as measured by the MP method of 0.2 cm³/g or more.

According to a second embodiment of the present disclosure, there is provided an electromagnetic wave absorber, including a base material and a porous carbon material containing, as a raw material, a plant-based material having a silicon (Si) content of 5% by mass or more, in which the porous carbon material has a specific surface area value as measured by the nitrogen BET method of 400 m²/g or more, a silicon (Si) content of 1% by mass or less, and a total pore volume of pores each having a diameter in the range from 1×10⁻⁹ m to 5×10⁻⁷ m as measured by the Non Localized Density Functional Theory (NLDFT) of 1.0 cm³/g or more.

A flexible printed wiring board according to an embodiment of the present disclosure includes a layer of the electromagnetic wave absorber according to the first or second embodiment of the present disclosure.

An electronic device according to an embodiment of the present disclosure includes the electromagnetic wave absorber according to the first or second embodiment of the present disclosure.

A method of producing the electromagnetic wave absorber according to the first embodiment of the present disclosure, including: carbonizing a plant-based material having a silicon (Si) content of 5% by mass or more at 400° C. to 1400° C., treating the material with one of acid and alkali to provide a porous carbon material having a specific surface area value as measured by the nitrogen BET method of 400 m²/g or more, a silicon (Si) content of 1% by mass or less, a pore volume as measured by the BJH method of 0.2 cm³/g or more, and a pore volume as measured by the MP method of 0.2 cm³/g or more, and mixing the porous carbon material with a base material. The term “mixing” involves the concepts such as kneading and dispersing. The same shall apply hereinafter.

A method of producing the electromagnetic wave absorber according to the second embodiment of the present disclosure, including: carbonizing a plant-based material having a silicon (Si) content of 5% by mass or more at 400° C. to 1400° C., treating the material with one of acid and alkali to provide a porous carbon material having a specific surface area value as measured by the nitrogen BET method of 400 m²/g or more, a silicon (Si) content of 1% by mass or less, and a total pore volume of pores each having a diameter in the range from 1×10⁻⁹ m to 5×10⁻⁷ m as measured by the Non Localized Density Functional Theory (NLDFT) of 1.0 cm³/g or more, and mixing the porous carbon material with a base material.

The electromagnetic wave absorber according to the first or second embodiment of the present disclosure, the electromagnetic wave absorber obtained by the method of producing the electromagnetic wave absorber according to the first or second embodiment of the present disclosure, the electromagnetic wave absorber in the flexible printed wiring board according to an embodiment of the present disclosure, and the electromagnetic wave absorber in the electronic device according to an embodiment of the present disclosure (hereinafter collectively referred to as “the electromagnetic wave absorber according to the present disclosure, etc.”) have moderate electric conductivity. In addition, the porous carbon material to be used has the prescribed specific surface area value, the prescribed various pore volume values, and the silicon (Si) content of 1% by mass or less. Therefore, the porous carbon material has a special hollow structure and has a significantly high filling ratio when the porous carbon material is dispersed in the base material. As a result, there may be provided an electromagnetic wave absorber showing high electromagnetic wave absorbing properties.

These and other objects, features and advantages of the present disclosure will become more apparent in light of the following detailed description of best mode embodiments thereof, as illustrated in the accompanying drawings.

Additional features and advantages are described herein, and will be apparent from the following Detailed Description and the figures.

### BRIEF DESCRIPTION OF THE FIGURES

FIG. 1 is a graph showing the measurement results of the transmission properties of the electromagnetic wave absorbers in Example 1, Comparative Examples 1-A, 1-B and 1-C; FIG. 2 is a graph showing measurement results of the accumulated pore volumes, determined by the MP method, of the porous carbon materials in Example 1, Comparative Example 1-A and Comparative Example 1-B, and activated carbon in Comparative Example 1-C;

FIG. 3 is a graph showing measurement results of the accumulated pore volumes, determined by the BJH method, of the porous carbon materials in Example 1, Comparative Example 1-A and Comparative Example 1-B, and activated carbon in Comparative Example 1-C;

FIG. 4 is a graph showing measurement results of the pore size distribution, determined by the Non Localized Density Functional Theory method, of the porous carbon materials in Example 1, Comparative Example 1-A and 1-B, and activated carbon in Comparative Example 1-C;

FIG. 5 is a graph showing the relation between the added parts by mass of the porous carbon material and the electromagnetic wave absorbing properties; and

FIG.6 is a schematic sectional view of the flexible printed wiring board in Example 2.

### DETAILED DESCRIPTION

Hereinafter, embodiments of the present disclosure will be described with reference to the drawings. The present disclosure is not limited to the embodiments, and various numerical values and materials mentioned in the description of the embodiments are merely examples. The embodiments will be described in the following order.

1. An electromagnetic wave absorber according to the first or second embodiment of the present disclosure, a flexible printed wiring board according to an embodiment of the present disclosure, an electronic device according to an embodiment of the present disclosure, and a method of producing the electromagnetic wave absorber according to the first or second embodiment of the present disclosure, general description

2. Example 1 (an electromagnetic wave absorber according to the first or second embodiment of the present disclosure, and a method of producing the electromagnetic wave absorber according to the first or second embodiment of the present disclosure)

3. Example 2 (a flexible printed wiring board according to an embodiment of the present disclosure, and an electronic device according to an embodiment of the present disclosure), and others

[An electromagnetic wave absorber according to the first or second embodiment of the present disclosure, a flexible printed wiring board according to an embodiment of the present disclosure, an electronic device according to an embodiment of the present disclosure, and a method of producing the electromagnetic wave absorbers according to the first or second embodiment of the present disclosure, general description]

In the electromagnetic wave absorber according to the first or second embodiment of the present disclosure, the electromagnetic wave absorber of the flexible printed wiring board according to an embodiment of the present disclosure, and the electromagnetic wave absorber of the electronic device according to an embodiment of the present disclosure desirably includes 100 parts by mass of a base material and 5 to 50 parts by mass of a porous carbon material. In the method of producing the electromagnetic wave absorber according to the first or second embodiment of the present disclosure, 100 parts by mass of a base material and 5 to 50 parts by mass of a porous carbon material are desirably mixed.

In the electromagnetic wave absorbers according to the embodiments of the present disclosure, including the above-described favorable embodiments, it is desirable that a surface resistance value is within the range from 1×10 n/sq to 1×10³ Ω/sq. The surface resistance value can be measured by the four-point probe method or the like. However, the methods should not be limited thereto.

In the electromagnetic wave absorbers according to the embodiments of the present disclosure, including the above-described favorable embodiments, the base material includes the resin. In this case, examples of the resin in the base material can be a silicone-based, acrylic-based, or epoxy-based high-molecular or low-molecular material (for example, rein, rubber etc.).

In the method of producing the electromagnetic wave absorber according to the first or second embodiment of the present disclosure, the base material is at least mixed with the porous carbon material. Other steps besides the mixing step (steps after the mixing step) may be involved in the method of producing the electromagnetic wave absorber. An example of such steps may be a step of heating after the mixing.

More specifically, when the base material is composed, for example, of a thermosetting resin, the uncured thermosetting resin is mixed and kneaded with the porous carbon material according to the first or second embodiment of the present disclosure to provide a precursor of the electromagnetic wave absorber. For example, an excipient may be added to the precursor of the electromagnetic wave absorber in a mold to mold it into a desired shape. Then, it may be heated to provide the electromagnetic wave absorber having the desired shape. Alternatively, when the base material is composed, for example, of a thermoplastic resin, the porous carbon material according to the first or second embodiment of the present disclosure may be mixed and kneaded with the thermoplastic resin while pellets or flakes of the thermoplastic resin are produced. Or, the pellets or flakes of the thermoplastic resin may be mixed and kneaded with the porous carbon material according to the first or second embodiment of the present disclosure. Using the resultant precursor of the electromagnetic wave absorber, the electromagnetic wave absorber having the desired shape can be provided, for example, by extrusion molding and injection molding. Furthermore, when the base material is composed, for example, of the thermoplastic resin, the porous carbon material according to the first or second embodiment of the present disclosure may be mixed and kneaded with the thermoplastic resin while pellets or flakes of the thermoplastic resin are produced, or the pellets or flakes of the thermoplastic resin may be mixed and kneaded with the porous carbon material according to the first or second embodiment of the present disclosure. Thus, the electromagnetic wave absorber can be provided.

The electromagnetic wave absorber according to the first or second embodiment of the present disclosure can have any form or shape including a sheet, a film, a plate, a box, an enclosure, a housing and the like.

The electromagnetic wave absorber according to the first or second embodiment of the present disclosure can be supported by a supporting member. Examples of the supporting member are a woven or non-woven fabric, and various architectural members such as a plastic film, plastic sheet, a plastic substrate, plaster board including decorated plaster board, calcium silicate board, slug plaster board, wooden fiber cement board, pulp cement board, wood chip cement board, sheet making plaster board, mortar board, rock wool board, wood based wall material, plywood, wood based fiberboard, decorated pulp cement board, glass-fiber or carbon-fiber board, ceramic board and the like, each of which having flexibility and being composed of an organic polymer, e.g., polymethyl methacrylate (PMMA), polyvinyl alcohol (PVA), polyvinyl phenol (PVP), polyethersulfone (PES), polyimide, polycarbonate (PC), polyethylene terephtalate (PET) and polyethylene naphthalate (PEN),.

The flexible printed wiring board including a flexible insulated substrate (base) may be based on a polyester film, a polyimide film or various non-woven fabrics. A single-sided or double-sided flexible printed wiring board may be used. The wiring may be coated with a so-called coverlay film or various resist films. For example, a layer of the electromagnetic wave absorber is formed on an outer surface of the flexible printed wiring board. Specifically, the layer of the electromagnetic wave absorber may be formed on an outer surface of the base, or on the coverlay film or the resist film. The layer of the electromagnetic wave absorber can be formed, for example, by printing an electromagnetic wave absorber, or printing and heating the precursor of the electromagnetic wave absorber, depending on the materials constituting the base material. The layer of the electromagnetic wave absorber formed on a part of the print wiring board by the above-described ways can also function as resistance.

Non-limiting examples of the electronic devices include a flexible printed wiring board, a television receiver, a game instrument, a mobile phone, a digital camera, a video camera and the like. Non-limiting examples of the form of the electromagnetic wave absorber applied to the electronic device include a sheet, a film, a plate, a box and the like.

The porous carbon material contains, as a raw material, the plant-based material. Non-limiting examples of the plant-based material are chaff and straws of rice (paddy), barley, wheat, rye, Japanese millet and foxtail millet; coffee beans, tea leaves (for example, leaves of green tea, black tea and the like); sugar canes (in particular, bagasse); corns (in particular, core of corn); fruit peels (for example, orange peel, banana peel and the like); reeds; Wakame seaweed stems (Undaria pinnatifida); terrestrial vascular plants; ferns; bryophytes; algae; and marine algae. These materials may be used alone, and a plurality of types of such materials may alternatively be used in combination, as a raw material. The shape and the form of the plant-based material are not especially limited. For example, the plant-based material may be chaff or straw itself, or the dried product. In addition, in terms of food processing of beer, liqueur or the like, a residue of various processing including fermentation, roasting, or extracting, can be applied. In particular, from the standpoint of recycling the industrial wastes, it is desirable that chaff and straws after processing, e.g., threshing, are used. These chaff and straws after processing are easily available in large amounts from, for example, agricultural cooperatives, alcoholic beverage makers, food companies and food processing companies.

In the method of producing the electromagnetic wave absorber according to the first or second embodiment of the present disclosure, the plant-based material is carbonized at 400° C. to 1400° C., and treated with one of acid and alkali to provide the porous carbon material. The resultant porous carbon material may be, for convenience, hereinafter simply referred to as “the porous carbon material according to the present disclosure”. The method may be, for convenience, hereinafter simply referred to as “the method of producing the porous carbon material”. The material obtained by carbonizing the plant-based material at 400° C. to 1400° C. and not yet treated with one of acid and alkali may be referred to as “the porous carbon material precursor” or “the carbonaceous substance”.

In the method of producing the porous carbon material, after the acid or alkali treatment, activation treatment can be performed. Or, after the activation treatment, the acid or alkali treatment may be performed. In the method of producing the porous carbon material including the above-described desirable form, although it depends on the plant-based material to be used, the plant-based material may be heated (pre-carbonized) at a temperature lower than the carbonizing temperature (for example, at 400° C. to 700° C.) in an oxygen-free state before the plant-based material is carbonized. As a result of extracting a tar component that would be produced during the carbonization, the tar component can be reduced or removed. The oxygen-free state can be achieved by, for example, providing an inert gas atmosphere including a nitrogen gas or an argon gas, providing a vacuum atmosphere, or almost steaming and baking the plant-based material. In the method of producing the porous carbon material, although it depends on the plant-based material to be used, the plant-based material may be immersed into alcohols (for example, methyl alcohol, ethyl alcohol and isopropyl alcohol) in order to decrease mineral components and a water content in the plant-based material or to prevent odor generation during the carbonization. Also, in the method of producing the porous carbon material, pre-carbonization may be performed thereafter. The plant-based material that produces a large amount of pyroligneous acid (tar and light crude oil) is an example that is desirably heated under the inert gas atmosphere. Seaweeds, which is the plant-based material containing a large amount of iodine and various minerals, is an example that is desirably pretreated with alcohol.

In the method of producing the porous carbon material, the plant-based material is carbonized at 400° C. to 1400° C. The carbonization herein means that organic substances (the plant-based material in the porous carbon material according to the present disclosure) are typically heated to convert them into carbonaceous substances (for example, see JIS M0104-1984). An example of the atmosphere for carbonization is an oxygen-free atmosphere. Specifically, there are a vacuum atmosphere, an inert gas atmosphere including a nitrogen gas or an argon gas, and an atmosphere where the plant-based material is almost steamed and baked. The rate of temperature increase to the carbonization temperature is not limited, but can be 1° C./min or more, desirably 3° C./min or more, more desirably 5° C./min or more under such atmosphere. The upper limit of the carbonization time may be 10 hours, desirably 7 hours and more desirably 5 hours, but not limited thereto. The lower limit of the carbonization time may be such that the plant-based material is surely carbonized. The plant-based material may be pulverized to the desired particle size, or classified, as necessary. The plant-based material may be pre-cleaned. Also, the resultant porous carbon material precursor or the porous carbon materials may be pulverized to the desired particle size, or classified, as necessary. In addition, the processed porous carbon material by the activation treatment may be pulverized to the desired particle size, or classified, as necessary. Furthermore, the finally resultant porous carbon material may be sterilized. The furnace used for carbonization is not limited in terms of a shape, a configuration and a structure, and may be a continuous furnace or a batch furnace.

In the method of producing the porous carbon material, as described above, the activation treatment can increase the numbers of micro pores each having a pore size of smaller than 2 nm (which will be described later). Examples of the activation treatment are gas activation and chemical activation. In the gas activation, oxygen, water vapor, carbon dioxide gas, air or the like can be used as an activator. Under the gas atmosphere, the porous carbon material is heated at 700° C. to 1400° C., desirably 700° C. to 1000° C., more desirably 800° C. to 1000° C. for several tens of minutes to several hours, so that the microstructure is grown by the volatile components and carbon molecules in the porous carbon material. More specifically, the heating temperature may be selected based on the types of the plant-based material, the kinds and concentration of the gas and the like, as necessary. In the chemical activation, the porous carbon material is activated by using zinc chloride, iron chloride, calcium phosphate, calcium hydroxide, magnesium carbonate, potassium carbonate, sulfuric acid or the like is used for activation instead of oxygen and water vapor used in the gas activation, and is cleaned with hydrochloric acid. The pH of the porous carbon material is adjusted by using an alkaline solution. Then, the porous carbon material is dried.

The surface of the porous carbon material according to the present disclosure may be chemical treated or molecular modified. For example, as one of the chemical treatments, a nitric acid treatment is performed to produce carboxyl groups on the surface. By the similar treatment as the activation treatment with water vapor, oxygen, alkali or the like, various functional groups such as a hydroxyl group, a carboxyl group, a ketone group or an ester group can be produced on the surface of the porous carbon material. In addition, when the porous carbon material is chemically reacted with chemical species or protein containing a hydroxyl group, a carboxyl group, an amino group or the like, which is able to react with the porous carbon material, the molecular modification may be possible.

In the method of producing the porous carbon material, silicon (Si) components are removed by the acid or alkali treatment from the carbonized plant-based material. The silicon components may be silicon oxides such as silicon dioxide, silicon oxide and a silicon oxide salt. By removing the silicon components in the carbonized plant-based material, there can be provided the porous carbon material having high specific surface area. In some cases, the silicon components in the carbonized plant-based material may be removed by a dry etching method.

The porous carbon material according to the present disclosure may contain magnesium (Mg), potassium (K), calcium (Ca), non-metal elements such as phosphorous (P) and sulfur (S), and metal elements such as transition elements. The amount of magnesium (Mg) may be from 0.01% by mass to 3% by mass, the amount of potassium (K) may be from 0.01% by mass to 3% by mass, the amount of calcium (Ca) may be from 0.05% by mass to 3% by mass, the amount of phosphorous (P) may be from 0.01% by mass to 3% by mass, and the amount of sulfur (S) may be from 0.01% by mass to 3% by mass, as examples. In terms of an increase in the specific surface area value, the amounts of these elements are desirably small. It should be appreciated that the porous carbon material may contain elements other than those described above, and the amounts thereof may be changed.

In the porous carbon material according to the present disclosure, various elements can be analyzed by, for example, energy dispersive spectrometry (EDS) using an energy dispersive X-ray spectrometer (for example, JED-2200F manufactured by JEOL Ltd.). The measurement conditions may include, for example, a scanning voltage of 15 kV and an illumination current of 10 μA.

The porous carbon material according to the present disclosure has many pores. The pores include “mesopores” having a pore size in the range from 2 nm to 50 nm, “macropores” having a pore size exceeding 50 nm and “micropores” having a pore size less than 2 nm. Specifically, the mesopores have many pores having a size of 20 nm or less, especially 10 nm or less, for example. In the porous carbon material according to the present disclosure, the pore volume as measured by the BJH method is desirably 0.2 cm³/g or more, more desirably 0.3 cm³/g or more, and even more desirably 0.4 cm³/g or more. The pore volume as measured by the MP method is desirably 0.2 cm³/g or more, more desirably 0.3 cm³/g or more, and even more desirably 0.4 cm³/g or more.

The nitrogen BET method is to measure the adsorption isotherm by adsorbing and desorbing admolecules, i.e. nitrogen, to/from an adsorbent (herein, the porous carbon material), and analyze the measured data by the BET equation represented by the equation (1). Based on the method, the specific surface area value, the pore volume and the like can be calculated. Specifically, when the specific area surface is calculated on the basis of the nitrogen BET method, the adsorption isotherm is first measured by adsorbing and desorbing the admolecules, i.e., nitrogen, to/from the porous carbon material. Then, [p/{Vₐ(p₀−p)}] is calculated from the measured adsorption isotherm based on the equation (1) or the deformed equation (1′) and is plotted to the relative pressure in equilibrium (p/p₀). The plot is considered as a straight line, and the slope s (=[(C−1)/(C Vₘ)]) and the intercept i (=[1/(C Vₘ)]) are calculated based on least squares method. The Vₘ and C are calculated from the calculated slope s and the intercept i based on the equations (2-1) and (2-2). The specific surface area a_{sBET} is calculated from Vₘ based on the equation (3) (see BELSORP-mini and BELSORP analysis software manual, pp. 62-66, made by BEL Japan Inc.). The nitrogen BET method is the measuring method in accordance with JIS R 1626-1996 “Measuring methods for the specific surface area of fine ceramic powders by gas adsorption using the BET method”.

Vₐ=(Vₘ C p)/[(p−p₀) Δ1(+C−1)(p/p₀)}] (1)

[p/{Vₐ(p₀−p)}]=(C−1)/(C Vₘ)](p/p₀)+[1/C Vₘ)] (1′)

Vₘ=1/(s+i) (2-1)

C=(s/i)+1 (2-2)

a_{sBET}=(Vₘ L σ)/22414 (3)

where,

Vₐ: Adsorbed amount

Vₘ: Adsorbed amount of monolayer

p: Nitrogen pressure in equilibrium

p₀: Saturated vapor pressure of nitrogen

L: The Avogadro number

σ: Cross-sectional area of adsorbed nitrogen

When the pore volume Vₚ is calculated by the nitrogen BET method, the adsorption data of the measured adsorption isotherm is, for example, linearly interpolated to determine the adsorbed amount V at relative pressure set for calculating the pore volume. The pore volume Vₚ can be calculated from the adsorbed amount V based on the equation (4) (see BELSORP-mini and BELSORP analysis software manual, pp. 62-65, made by BEL Japan Inc.). The pore volume determined by the nitrogen BET method may be referred to simply as “the pore volume”.

Vₚ=(V/22414)×(M_{g}/ρ_{g}) (4)

where,

V: Adsorbed amount at relative pressure

M_{g}: Molecular weight of nitrogen

ρ_{g}: Density of nitrogen

The pore size of the mesopores can be calculated as, for example, the pore distribution from the change rate of the pore volume to the pore size based on the BJH method. The BJH method is widely used as a method for pore distribution analysis. When the pore distribution is analyzed by the BJH method, the desorption isotherm is first measured by adsorbing and desorbing the admolecules, i.e., nitrogen, to/from the porous carbon material. Then, based on the measured desorption isotherm, the thickness of the adsorbed layer is determined when the adsorbed molecules (for example, nitrogen) that fill the pores are gradually adsorbed/desorbed, and the inner diameter (twice the length of core radius) of the pores is determined. Based on the equation (5), the pore radius rₚ is calculated. Based on the equation (6), the pore volume is calculated. Then, the pore distribution curve is obtained by plotting the change rate of the pore volume (dVₚ/drₚ) to the pore size (2rₚ) based on the pore radius and the pore volume (see BELSORP-mini and BELSORP analysis software manual, pp. 85-88, made by BEL Japan Inc.).

rₚ=t+rₖ (5)

Vₚₙ=Rₙ dVₙ−Rₙ dtₙ c ΣAₚⱼ (6)

where,

Rₙ=rₚₙ²/(rₖₙ−1+dtₙ)² (7)

where,

rₚ: Pore radius

rₖ: Core radius (inner diameter/2) when the adsorbed layer having a thickness oft is adsorbed on the inner wall of the pore having the pore radius rₚ at the pressure

Vₚₙ: Pore volume at the time of n-th adsorption/desorption of nitrogen

dVₙ: Amount of change at the time of n-th adsorption/desorption of nitrogen

dtₙ: Amount of change in the thickness tₙ of the adsorbed layer at the time of n-th adsorption/desorption of nitrogen

rₖₙ: Core radius at the time of n-th adsorption/desorption of nitrogen

c: Fixed value

rₚₙ: Pore radius at the time of n-th adsorption/desorption of nitrogen

In addition, ΣAₚⱼ represents the integration value of the areas of the pore walls from j=1 to j=n-1.

The pore size of the micropores can be calculated as, for example, the pore distribution from the change rate of the pore volume to the pore size based on the MP method. When the pore distribution is analyzed by the MP method, the adsorption isotherm is first measured by adsorbing nitrogen to the porous carbon material. Then, the adsorption isotherm is converted (t plotted) into the pore volume to the thickness t of the adsorbed layer. The pore distribution curve can be obtained based on curvature (amount of change in the pore volume to amount of change in the thickness t of the adsorbed layer) of the plot (see BELSORP-mini and BELSORP analysis software manual, pp. 72-73, 82, made by BEL Japan Inc.).

The Non Localized Density Functional Theory (NLDFT) method specified in JIS Z8831-2:2010 “Pore Size Distribution and Porosity of Powders (Solid Materials)—Part 2: Method of Measuring Mesopores and Macropores using Gas Absorption” and JIS Z8831-3:2010 “Pore Size Distribution and Porosity of Powders (Solid Materials)—Part 3: Method of Measuring Micropores using Gas Absorption” employs software accompanying the automatic specific surface area/pore distribution measuring apparatus “BELSORP-MAX” manufactured by BEL JAPAN, INC. as analyzing software. An analysis is carried out using a model having a cylindrical shape and assuming carbon black (CB), as prerequisites for the analysis. Then, a distribution function for pore distribution parameters is set as “no-assumption”, and smoothing will be performed ten times on distribution data thus obtained.

The porous carbon material precursor is treated with an acid or alkali. For example, the porous carbon material precursor may be immersed into a water solution of an acid or alkali. Or, the porous carbon material precursor may be reacted with an acid or alkali in the vapor phase. More specifically, the acid treatment may be carried out using an acidic fluorine compound as an acid such as a hydrogen fluoride, hydrofluoric acid, ammonium fluoride, calcium fluoride, or sodium fluoride. When a fluorine compound is used, the amount of fluorine is desirably four times the amount of silicon in silicon components included in the porous carbon material precursor, and a water solution of the fluorine compound desirably has a concentration of 10% by mass or more. When silicon components (e.g., silicon dioxide) included in the porous carbon material precursor are removed by the use of a hydrofluoric acid, silicon dioxide reacts with the hydrofluoric acid as indicated by formula (A) or (B), and silicon can be eliminated as hydrogen hexafluorosilicate (H₂SiF₆) or silicon tetrafluoride (SiF₄). Thus, a porous carbon material is obtained. The material may thereafter be washed and dried.

SiO₂+6HF→H₂SiF₆+2H₂O (A)

SiO₂+4HF→SiF₄+2H₂O (B)

When the precursor is treated with alkali (base), the alkali may be sodium hydroxide. When a water solution of alkali is used, the pH of the water solution may be 11 or more. When silicon components (e.g., silicon dioxide) included in the porous carbon material precursor are removed by the use of a water solution of sodium hydroxide, silicon dioxide is made to react as indicated by formula (C) by the heating of the water solution of sodium hydroxide. The silicon dioxide can be eliminated as sodium silicate (Na₂SiO₃) resulting from the reaction. Thus, a porous carbon material is obtained. When the precursor is treated by the reaction caused by sodium hydroxide in the vapor phase, sodium hydroxide in a solid state is heated to cause it to react as indicated by formula (C). The silicon dioxide can be eliminated as sodium silicate (Na₂SiO₃) resulting from the reaction. Thus, a porous carbon material is obtained. The material may thereafter be washed and dried.

SiO₂+2NaOH→Na₂SiO₃+H₂O (C)

The porous carbon material according to the present disclosure may be a porous carbon material including holes having three-dimensional regularity, for example, as disclosed in Japanese Unexamined Patent Application Publication No. 2010-106007 (a porous carbon material having what is called an inverse opal structure). Specifically, the porous carbon material has spherical holes in a three dimensional arrangement having an average diameter in the range from 1×10⁻⁹ m to 1×10⁻⁵ m and having a surface area of 3×10² m²/g or more. Desirably, the holes are arranged in a disposition similar to a crystalline structure in a macroscopic point of view. Alternatively, the porous carbon material has holes arranged on a surface thereof in a disposition similar to the alignment of a (111) plane of a face-centered cubic structure in a macroscopic point of view.

### EXAMPLE 1

Example 1 of the present disclosure relates to the electromagnetic wave absorber according to the first or second embodiment of the present disclosure and the method of producing the electromagnetic wave absorber according to the first or second embodiment of the present disclosure.

As expressed in accordance with the first embodiment of the present disclosure, Example 1 of the present disclosure is the electromagnetic wave absorber, including a base material and a porous carbon material containing, as a raw material, a plant-based material having a silicon (Si) content of 5% by mass or more, in which the porous carbon material has a specific surface area value as measured the nitrogen

BET method of 400 m²/g or more, a silicon (Si) content of 1% by mass or less, a pore volume as measured by the BJH method of 0.2 cm³/g or more, and a pore volume as measured by the MP method of 0.2 cm³/g or more.

As expressed in accordance with the second embodiment of the present disclosure, Example 1 of the present disclosure is the electromagnetic wave absorber, including a base material and a porous carbon material containing, as a raw material, a plant-based material having a silicon (Si) content of 5% by mass or more, in which the porous carbon material has a specific surface area value as measured by the nitrogen BET method of 400 m²/g or more, a silicon (Si) content of 1% by mass or less, and a total pore volume of pores each having a diameter in the range from 1×10⁻⁹ m to 5×10⁻⁷ m as measured by the Non Localized Density Functional Theory (NLDFT) of 1.0 cm³/g or more. It is desirable that the ratio of the pore volume of the pores having pore sizes in the range from 3 nm to 20 nm to the total pore volume described above is 0.2 or more.

In Example 1, the plant-based material which is the raw material of the porous carbon material is rice (paddy) chaff. Also in Example 1, the base material includes a resin. Specifically, the base material was a cured acrylic ester copolymer (more specifically, SG-P3 manufactured by Nagase ChemteX Corporation). A hardener was HX3748 manufactured by Asahi Kasei Chemicals Corporation. The porous carbon material in Example 1 is obtained by carbonizing chuff serving as a raw material to convert it into a carbonaceous substance (porous carbon material precursor) and thereafter treating the substance with an acid. A method of manufacturing the electromagnetic wave absorber in Example 1 will be described below.

In the process of manufacturing the electromagnetic wave absorber in Example 1, the plant-based material was carbonized at a temperature in the range from 400° C. to 1400° C., and was thereafter treated with an acid or alkali, so that the porous carbon material was obtained. First, a heating process (a preliminary carbonizing process) was performed on chaff under inert gas. Specifically, the chaff was carbonized by heating at 500° C. for 3 hours in a flow of nitrogen gas, and a carbide was obtained. Such a process makes it possible to reduce or eliminate tar components which will otherwise be generated at a subsequent carbonizing step. Thereafter, 10 grams of the carbide was put in a crucible made of alumina, and the temperature of the carbide was raised to 800° C. at a rate of 5° C./min in a flow of nitrogen gas (5 liters/min). The carbide was carbonized at 800° C. for one hour and converted into a carbonaceous substance (porous carbon material precursor), and the substance was cooled down to room temperature. The nitrogen gas was kept flowing during carbonizing and cooling. Next, the porous carbon material precursor was acid-treated by immersing in a water solution of 46 vol % hydrofluoric acid overnight, and the precursor was washed with water and ethyl alcohol until it reached a pH of 7. Next, the precursor was dried at 120° C. and heated to 900° C. in a flow of nitrogen. Then, the precursor was activated by heating at 900° C. for 3 hours in a flow of water vapor. The porous carbon material in Example 1 was obtained.

As “Comparative Example 1-A”, the above-mentioned carbonaceous substance (a porous carbon material precursor) was used. As “Comparative Example 1-B”, the sample that was activated but was not treated with acid was used. As “Comparative Example 1-C”, coconut shell activated carbon (manufactured by Wako Pure Chemical Industries, Ltd.) was used.

A nitrogen absorption/desorption test was carried out to find the specific surface areas and the pore volumes, using a measuring apparatus BELSORP-mini (manufactured by BEL JAPAN, INC.). The measurement was carried out at a measurement relative pressure in equilibrium (p/p₀) of 0.01 to 0.99. The specific surface areas and the pore volumes were calculated using BELSORP analysis software. Pore size distributions of mesopores and micropores were obtained by conducting a nitrogen absorption/desorption test using the above-mentioned measuring apparatus and carrying out calculations using the BELSORP analysis software based on the BJH method and the MP method. Further, the analysis based on the Non Localized Density Functional Theory (NLDFT) was carried out using software accompanying an automatic specific surface area/pore distribution measuring apparatus “BELSORP-MAX” manufactured by BEL JAPAN, INC. Prior to the measurement, the samples were subjected to drying at 200° C. for 3 hours as a pre-process.

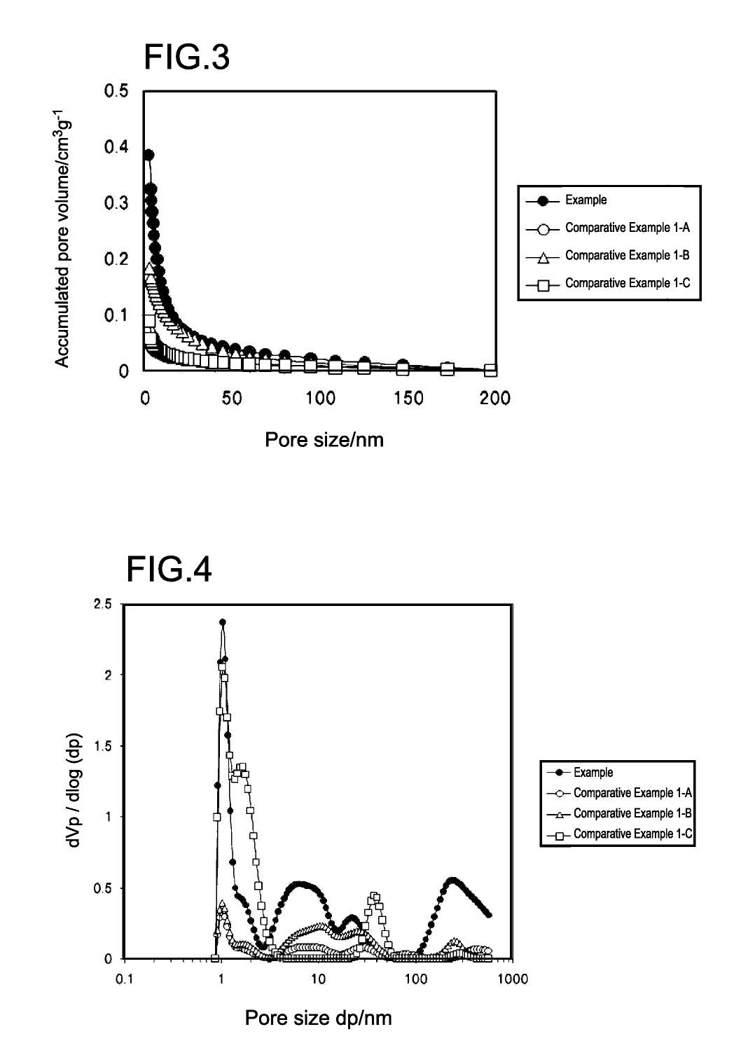

The specific surface area and the pore volume of each of the porous carbon materials in Example 1, Comparative Example 1-A and Comparative Example 1-B, and activated carbon in Comparative Example 1-C were measured. Table 2 shows the results. In Table 2, the term “specific surface area” and “total pore volume” mean a specific surface area in m²/g and a total pore volume in cm³/g, respectively, both obtained according to the nitrogen BET method. The terms “BJH method” and “MP method” refer to a pore (mesopore to macropore) volume result as measured by the BJH method, and a pore (micropore) volume result as measured by the MP method, respectively. The units are in cm³/g. FIG. 2 is a graph showing measurement results of the accumulated pore volumes, determined by the MP method, of the porous carbon materials in Example 1, Comparative Example 1-A and Comparative Example 1-B, and activated carbon in Comparative Example 1-C. FIG. 3 is a graph showing measurement results of the accumulated pore volumes, determined by the BJH method, of the porous carbon materials in Example 1, Comparative Example 1-A and Comparative Example 1-B, and activated carbon in Comparative Example 1-C. FIG. 4 is a graph showing measurement results of the pore size distribution, determined by the Non Localized Density Functional Theory method, of the porous carbon materials in Example 1, Comparative Example 1-A and Comparative Example 1-B, and activated carbon in Comparative Example 1-C. Table 1 shows the total pore volume (in cm³/g) of pores each having a diameter in the range from 1×10⁻⁹ m to 5×10⁻⁷ m measured by the Non Localized Density Functional Theory.

TABLE 1

| | |
|---|---|
| Example 1 | 1.34 |
| Comparative Example 1-A | 0.188 |
| Comparative Example 1-B | 0.335 |
| Comparative Example 1-C | 0.894 |

TABLE 2

| | Specific | Total pore | | |
|---|---|---|---|---|
| | surface area | volume | BJH method | MP method |
| Example 1 | 1200 | 0.777 | 0.384 | 0.483 |
| Comparative | 172 | 0.129 | 0.069 | 0.065 |
| Example 1-A | | | | |
| Comparative | 258 | 0.260 | 0.183 | 0.067 |
| Example 1-B | | | | |
| Comparative | 1270 | 0.579 | 0.088 | 0.556 |
| Example 1-C | | | | |

The porous carbon material in Example 1 has a pore volume of 0.2 cm³/g or more as measured by the BJH method and also has a pore volume of 0.2 cm³/g or more as measured by the MP method. In contrast, the porous carbon material in Comparative Example 1-A has a pore volume of less than 0.2 cm³/g as measured by the BJH method and also has a pore volume of less than 0.2 cm³/g as measured by the MP method. Also, the porous carbon material in Comparative Example 1-B has a pore volume of less than 0.2 cm³/g as measured by the MP method. In addition, the activated carbon in Comparative Example 1-C has a pore volume of less than 0.2 cm³/g as measured by the BJH method. A total pore volume (in cm³/g) of pores each having a diameter in the range from 1×10⁻⁹ m to 5×10⁻⁷ m as measured by the Non Localized Density Functional Theory (NLDFT) is 1.0 cm³/g or more in Example 1. The total pore volume is less than 1.0 cm³/g in Comparative Examples 1-A, 1-B and 1-C, respectively.

Fifty parts by mass of the porous carbon material in each of Example 1, Comparative Example 1-A and 1-B, or activated carbon in Comparative Example 1-C, 100 parts by mass of an uncured acrylic ester copolymer, SG-P3 manufactured by Nagase ChemteX Corporation, to which a hardener HX3748 manufactured by Asahi Kasei Chemicals Corporation was added, and toluene as a diluent were mixed (kneaded), and heated (pretreated) to evaporate toluene into a sheet shape, which was heated at 120° C. for 30 minutes. As a result, the electromagnetic wave absorber in each of Example 1 and Comparative Examples 1-A, 1-B and 1-C was provided. The resultant sheet-shaped electromagnetic wave absorber was hot-pressed to be planarized and densified, and was cut to an electromagnetic wave absorber sheet.

Table 3 shows a surface resistance value (in Ω/sq) and thickness (in μm) of the electromagnetic wave absorber in each of Example 1 and Comparative Examples 1-A, 1-B and 1-C.

TABLE 3

| | Surface resistance value | Thickness |
|---|---|---|
| Example 1 | 6.0 × 10² | 60 |
| Comparative Example 1-A | 3.4 × 10⁴ | 80 |
| Comparative Example 1-B | 2.5 × 10⁴ | 80 |
| Comparative Example 1-C | 4.1 × 10³ | 70 |

Transmission properties of the electromagnetic wave absorbers in Example 1, Comparative Examples 1-A, 1-B and 1-C were evaluated using the micro strip line (MSL) method. Specifically, a 20×20 mm sample of each electromagnetic wave absorber was directly mounted on a center of a micro strip line substrate (50Ω). A reflection property S11 [in dB] and a permeation property S21 [in dB] were determined with/without the samples. An electromagnetic wave absorption ratio (ΔLoss) in the micro strip line was evaluated from S11 and S21. In order to provide uniform adhesion between the micro strip and the sample, an acrylic resin (having a mass of 30 gram), which does not affect on the measurement of the electromagnetic wave absorption ratio (ΔLoss), was disposed on the sample. A loss property (Loss) and the electromagnetic wave absorption ratio (ΔLoss) are calculated by the following equations, where “Loss (A)” and “Loss (B)” represent a measurement result obtained by directly mounting the sample of the electromagnetic wave absorber on the center of the micro strip line substrate (50Ω) and a measurement result obtained only with the micro strip line substrate (50Ω) without the sample of the electromagnetic wave absorber, respectively.

Loss=1-10^{(S11/10)}−10^{(S21/10)}

ΔLoss=Loss (A)−Loss (B)

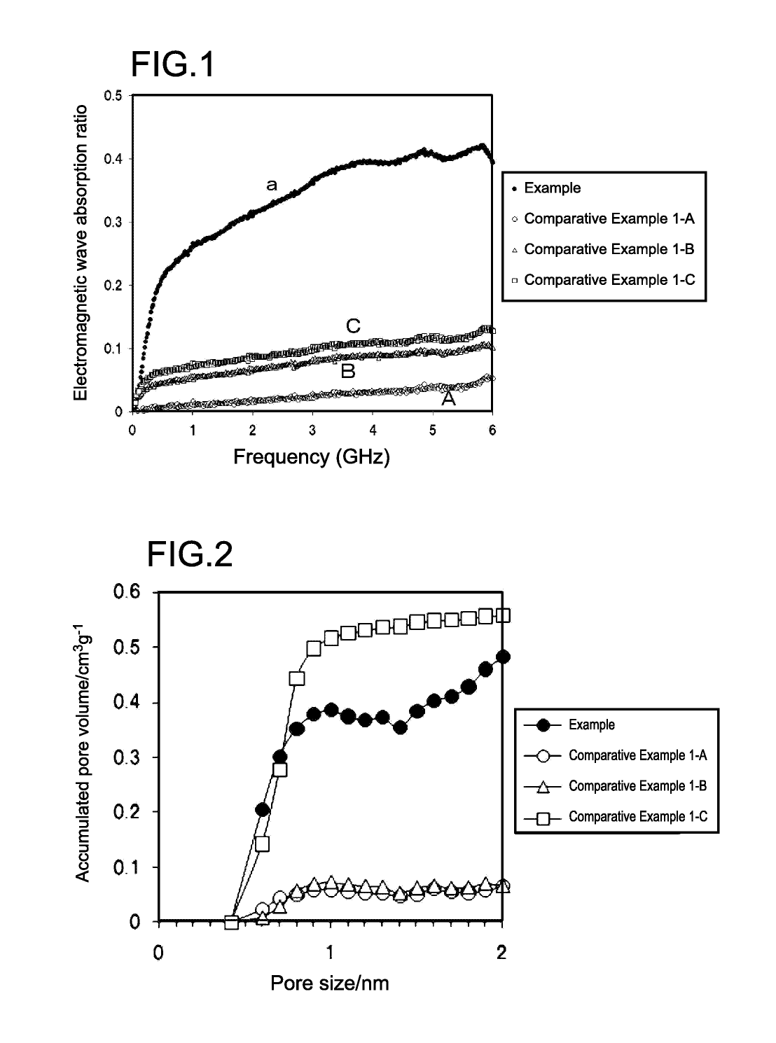

FIG. 1 shows the measurement results of the transmission properties of the electromagnetic wave absorbers in Example 1, Comparative Examples 1-A, 1-B and 1-C. In FIG. 1, a horizontal axis represents measured frequencies (in gigaherz), and a vertical axis (the electromagnetic wave absorption ratio) represents ΔLoss values derived from the aforementioned equations. Also, in FIG. 1, “a” represents the measurement result of the electromagnetic wave absorber in Example 1, “A” represents the measurement result of the electromagnetic wave absorber in Comparative Example 1-A, “B” represents the measurement result of the electromagnetic wave absorber in Comparative Example 1-B, and “C” represents the measurement result of the electromagnetic wave absorber in Comparative Example 1-C.

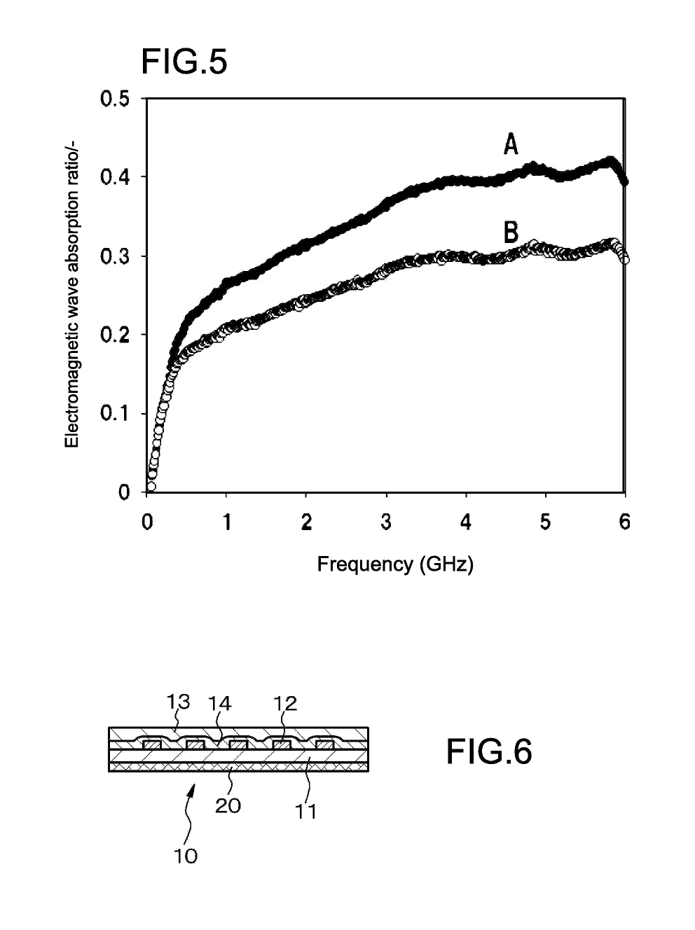

FIG. 1 also reveals that the electromagnetic wave absorption ratio of the electromagnetic wave absorber in Example 1 is higher in all frequencies than those of the electromagnetic wave absorbers in Comparative Example 1-A, 1-B and 1-C. Also, there is a correlation between the electromagnetic wave absorption ratios and the surface resistance values shown in Table 3. In other words, it is found that the lower the surface resistance value is, the higher the electromagnetic wave absorbing properties are. In addition, as shown in FIG. 5, when the added parts by mass of the porous carbon material are high, the electromagnetic wave absorbing properties become better. In FIG. 5, the curve “A” represents data obtained when 50 parts by mass of the porous carbon material were added to 100 parts by mass of the base material, and the curve “B” represents data obtained when 25 parts by mass of the porous carbon material were added to 100 parts by mass of the base material. When the surface resistance value is too small, physical properties of the electromagnetic wave absorber approach those of the metal, resulting in a decrease in the electromagnetic wave absorption ratio (ΔLoss). Consequently, it is desirable that the surface resistance value is adjusted within the range from 1×10 Ω/sq to 1×10³ Ω/sq. It is considered that high electromagnetic wave absorbing properties can be obtained by using the porous carbon material in Example 1 having a special microstructure, a special hollow structure or a special bulk structure. When the added parts by mass of the porous carbon material according to the Example 1 were decreased, the electromagnetic wave absorbing properties were gradually lowered. At less than 5 parts by mass, no sufficient electromagnetic wave absorbing properties could be provided.

### EXAMPLE 2

Example 2 relates to the flexible printed wiring board according to an embodiment of the present disclosure and the electronic device according to an embodiment of the present disclosure.

FIG. 6 is a schematic sectional view of the flexible printed wiring board (which is also the electronic device) in Example 2. The flexible printed wiring board 10 in Example 2 includes a layer of an electromagnetic wave absorber 20. Specifically, the layer of the electromagnetic wave absorber 20 is formed on an outer surface of the printed wiring board 10 in Example 2, and includes the electromagnetic wave absorber in Example 1. More specifically, the flexible printed wiring board (in particular, a single-sided flexible printed wiring board) 10 includes a flexible insulated substrate (base) 11 made of a polyimide film, and a wiring 12 made of a copper foil, which is covered by a so-called coverlay film 13. The coverlay film 13 is made of a polyimide film. An adhesive layer 14 is formed on the coverlay film 13. The layer of the electromagnetic wave absorber 20 is formed on an outer surface of the insulated substrate 11 using the raw material described in Example 1 by printing and heating.

The present disclosure has been described based on the favorable embodiments thereof, and the present disclosure is not limited to the embodiments and may be modified in various ways. The electromagnetic wave absorber according to an embodiment of the present disclosure can be used together with a woven or non-woven fabric, for example. Specifically, the electromagnetic wave absorber according to an embodiment of the present disclosure may be kneaded into fiber in advance and spun into the woven or non-woven fabric, or may be attached to the woven or non-woven fabric using a binder or the like. Using the woven or non-woven fabric, a cloth, a curtain, a wall paper or the like may be produced. While the chaff used as the raw material of the porous carbon material is made from rice chaff in Examples, other plants may be used. For example, other usable plants include straws, reeds, stems of Wakame seaweed, terrestrial vascular plants, ferns, bryophytes, algae, and marine algae. Those plants may be used alone, and a plurality of types of such plants may alternatively be used in combination. Specifically, straws of paddy (e.g., Isehikari produced in Kagoshima prefecture in Japan) may be the plant-based material which is the raw material of the porous carbon material. The straws may be carbonized into a carbonaceous substance (a porous carbon material precursor), and the carbonaceous substance may be treated with an acid to obtain the porous carbon material. Alternatively, gramineous reeds may be the plant-based material which is the raw material of the porous carbon material. The gramineous reeds may be carbonized into a carbonaceous substance (a porous carbon material precursor), and the carbonaceous substance may be treated with an acid to obtain the porous carbon material. Advantages similar to those described above were achieved by the porous carbon material obtained by treating a material using alkali (base) such as a water solution of sodium hydroxide instead of a water solution of hydrofluoric acid.

Alternatively, stems of Wakame seaweed (cropped in Sanriku, Iwate prefecture in Japan) may be the plant-based material which is the raw material of the porous carbon material. The stems of Wakame seaweed may be carbonized into a carbonaceous substance (porous carbon material precursor), and the carbonaceous substance may be treated with an acid to obtain the porous carbon material. Specifically, first, the stems of Wakame seaweed are heated at a temperature of, for example, 500° C. and carbonized. The stems of Wakame seaweed may be treated with alcohol before the heating. Specifically, the raw material may be immersed in ethyl alcohol or the like. As a result, moisture included in the raw material is reduced, and the process also allows elution of elements other than carbon and mineral components which will otherwise be included in the porous carbon material finally obtained. The treatment with alcohol suppresses the generation of gasses during the carbonizing process. More specifically, stems of Wakame seaweed are immersed in ethyl alcohol for 48 hours. It is desirable to perform an ultrasonic process on the material in ethyl alcohol. The stems of Wakame seaweed are then carbonized by being heated at 500° C. for 5 hours in a flow of nitrogen gas to obtain a carbide. Such a process (preliminary carbonizing process) can reduce or eliminate tar components which will otherwise be generated at the subsequent carbonizing step. Thereafter, 10 grams of the carbide is put in a crucible made of alumina, and the temperature of the carbide is raised to 1000° C. at a rate of 5° C./min. in a flow of nitrogen gas (10 liters/min) The carbide is carbonized at 1000° C. for 5 hours and converted into a carbonaceous substance (porous carbon material precursor), and the substance is cooled down to room temperature. The nitrogen gas is kept flowing during carbonizing and cooling. Next, the porous carbon material precursor is acid-treated by immersion in a water solution of 46 vol % hydrofluoric acid overnight, and the precursor is washed with water and ethyl alcohol until it reaches a pH of 7. Finally, the precursor is dried so that a porous carbon material will be obtained.

The present disclosure may have the following configurations.

[1] <<An Electromagnetic Wave Absorber: First Embodiment>>

An electromagnetic wave absorber, including a base material and a porous carbon material containing, as a raw material, a plant-based material having a silicon content of 5% by mass or more, in which the porous carbon material has a specific surface area value as measured by the nitrogen BET method of 400 m²/g or more, a silicon content of 1% by mass or less, a pore volume as measured by the BJH method of 0.2 cm³/g or more, and a pore volume as measured by the MP method of 0.2 cm³/g or more.

[2] <<An Electromagnetic Wave Absorber: Second Embodiment>>

An electromagnetic wave absorber, including a base material and a porous carbon material containing, as a raw material, a plant-based material having a silicon content of 5% by mass or more, in which the porous carbon material has a specific surface area value as measured by the nitrogen BET method of 400 m²/g or more, a silicon content of 1% by mass or less, and a total pore volume of pores each having a diameter in the range from 1×10⁻⁹ m to 5×10⁻⁷ m as measured by the Non Localized Density Functional Theory of 1.0 cm³/g or more.

[3] <<An Electromagnetic Wave Absorber: Third Embodiment>>

The electromagnetic wave absorber according to [1] or [2] above, in which the base material has 100 parts by mass and the porous carbon material has 5 to 50 parts by mass.

[4] <<The electromagnetic wave absorber according to any one of [1] to [3] above, in which a surface resistance value is within the range from 1×10 Ω/sq to 1×10³ Ω/sq.

[5] <<A Flexible Printed Wiring Board>>

A flexible printed wiring board, including a layer of the electromagnetic wave absorber according to any one of [1] to [4] above.

[6] <<An Electronic Device>>

An electronic device, including a layer of the electromagnetic wave absorber according to any one of [1] to [4] above.

[7] <<A Method of Producing the Electromagnetic Wave Absorber: First Embodiment>>

A method of producing an electromagnetic wave absorber, including, carbonizing a plant-based material having a silicon content of 5% by mass or more at 400° C. to 1400° C., treating the material with one of acid and alkali to provide a porous carbon material having a specific surface area value as measured by the nitrogen BET method of 400 m²/g or more, a silicon content of 1% by mass or less, a pore volume as measured by the BJH method of 0.2 cm³/g or more, and a pore volume as measured by the MP method of 0.2 cm³/g or more, and mixing the porous carbon material with a base material.

[8] <<A Method of Producing the Electromagnetic Wave Absorber: Second Embodiment>>

A method of producing an electromagnetic wave absorber, including, carbonizing a plant-based material having a silicon content of 5% by mass or more at 400° C. to 1400° C., treating the material with one of acid and alkali to provide a porous carbon material having a specific surface area value as measured by the nitrogen BET method of 400 m²/g or more, a silicon content of 1% by mass or less, and a total pore volume of pores each having a diameter in the range from 1×10⁻⁹ m to 5×10⁻⁷ m as measured by the Non Localized Density Functional Theory of 1.0 cm³/g or more, and mixing the porous carbon material with a base material.

[9] The method according to [7] or [8] above, in which 100 parts by mass of the base material is mixed with 5 to 50 parts by mass of the porous carbon material.

Embodiments and examples of the present disclosure have been described, but the technology is not limited to those described above in the embodiments and examples, and various modifications are possible within the technological scope of the present disclosure.

For example, the numerical values, structures, configurations, shapes and materials described above in embodiments and examples are nothing but examples and numerical values, structures, configurations, shapes, materials and others different from them may be used, as necessary.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. An electromagnetic wave absorber, comprising:
a base material; and
a porous carbon material containing, as a raw material, a plant-based material having a silicon content of 5% by mass or more, wherein
the porous carbon material has a specific surface area value as measured by the nitrogen BET method of 400 m²/g or more, a silicon content of 1% by mass or less, a pore volume as measured by the BJH method of 0.2 cm³/g or more, and a pore volume as measured by the MP method of 0.2 cm³/g or more.

2. An electromagnetic wave absorber, comprising:
a base material; and
a porous carbon material containing, as a raw material, a plant-based material having a silicon content of 5% by mass or more, wherein
the porous carbon material has a specific surface area value as measured by the nitrogen BET method of 400 m²/g or more, a silicon content of 1% by mass or less, and a total pore volume of pores each having a diameter in the range from 1×10⁻⁹ m to 5×10⁻⁷ m as measured by the Non Localized Density Functional Theory of 1.0 cm³/g or more.

3. The electromagnetic wave absorber according to claim 1, wherein
the base material has 100 parts by mass and the porous carbon material has 5 to 50 parts by mass.

4. The electromagnetic wave absorber according to claim 1, wherein
a surface resistance value is within the range from 1×10 Ω/sq to 1×10³ Ω/sq.

5. A flexible printed wiring board, comprising
a layer of the electromagnetic wave absorber according to claim 1.

6. An electronic device, comprising
the electromagnetic wave absorber according to claim 1.

7. A method of producing an electromagnetic wave absorber, comprising:
carbonizing a plant-based material having a silicon content of 5% by mass or more at 400° C. to 1400° C.;
treating the material with one of acid and alkali to provide a porous carbon material having a specific surface area value as measured by the nitrogen BET method of 400 m²/g or more, a silicon content of 1% by mass or less, a pore volume as measured by the BJH method of 0.2 cm³/g or more, and a pore volume as measured by the MP method of 0.2 cm³/g or more; and
mixing the porous carbon material with a base material.

8. A method of producing an electromagnetic wave absorber, comprising:
carbonizing a plant-based material having a silicon content of 5% by mass or more at 400° C. to 1400° C.;
treating the material with one of acid and alkali to provide a porous carbon material having a specific surface area value as measured by the nitrogen BET method of 400 m²/g or more, a silicon content of 1% by mass or less, and a total pore volume of pores each having a diameter in the range from 1×10⁻⁹ m to 5×10⁻⁷ m as measured by the Non Localized Density Functional Theory of 1.0 cm³/g or more; and
mixing the porous carbon material with a base material.

9. The method according to claim 7, wherein
100 parts by mass of the base material is mixed with 5 to 50 parts by mass of the porous carbon material.
